(19) United States
(12) Patent Application Publication
(10) Pub. No.: US 2018/0130780 A1
(43) Pub. Date: May 10, 2018

(54) INTERPOSER TRANSMISSION LINE USING MULTIPLE METAL LAYERS

(71) Applicants: ADVANCED MICRO DEVICES, SUNNYVALE, CA (US); ATI TECHNOLOGIES ULC, MARKHAM (CA)

(72) Inventors: DEAN GONZALES, FORT COLLINS, CO (US); MARK EDWARD FRANKOVICH, MARKHAM (CA); JULIUS E. DIN, SUNNYVALE, CA (US); GERALD R. TALBOT, BOXBOROUGH, MA (US); JOSEPH R. SIEGEL, BOXBOROUGH, MA (US); YAN ZHANG, SHANGHAI (CN)

(21) Appl. No.: 15/354,060

(22) Filed: Nov. 17, 2016

(30) Foreign Application Priority Data
Nov. 4, 2016 (CN) 201610962420.7

(51) Int. Cl. H01L 25/18; H01L 25/065; H01L 23/538; H01L 21/48

(52) U.S. Cl. CPC H01L 25/18; H01L 25/0652; H01L 21/4846; H01L 23/5386; H01L 23/5384

(57) ABSTRACT

An interposer includes transmission lines formed of multiple metal layers disposed in a stack orthogonal to a plane formed by a primary surface of a substrate upon which the interposer is mounted. The use of multiple metal layers to form the transmission lines results in each transmission line having a height, or thickness, that is at least equal to the width of the transmission line. By using multiple metal layers, a transmission line can be formed having a height or thickness that is more than twice or more than three times the width of the transmission line.

### BACKGROUND

To enhance processing efficiency, reduce power consumption, and achieve a small footprint, a processing system can be formed in a three-dimensional (3D) integrated circuit (IC). In such an IC, multiple dies can be vertically stacked and through silicon vias (TSVs) employed to form connections between the dies. Thus, for example, a set of memory dies can be stacked above a logic die including circuitry that forms a central processing unit (CPU) or graphics processing unit (GPU). Arranging the dies in a stack facilitates efficient communication between the dies at relatively low power while achieving a small footprint for the processing system. However, such “full-stack” arrangements can have limitations, such as thermal dissipation, that can negatively impact performance of the processing system. To address such limitations, some processing systems employ a 3D IC architecture wherein the logic die is disposed laterally to the stack of memory dies, with both the logic die and stack of memory dies mounted on top of an interposer die. The interposer die includes a set of transmission lines to connect an input/output (I/O) interface of the logic die to the memory dies. However, in order to maintain sufficient signal fidelity, conventional transmission line designs can consume a large amount of area and undesirably increase the footprint of the IC.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of an integrated circuit device including an interposer incorporating transmission lines that employ multiple metal layers in accordance with some embodiments.

FIG. 2 is a cross section of the transmission lines of FIG. 1 in accordance with some embodiments.

FIG. 3 is a cross section of the transmission lines of FIG. 1 in accordance with some other embodiments.

FIG. 4 is a cross section of the transmission lines of FIG. 1 in accordance with still other embodiments.

FIG. 5 is a flow diagram of a method of forming transmission lines of an interposer having multiple metal layers in accordance with some embodiments.

### DETAILED DESCRIPTION

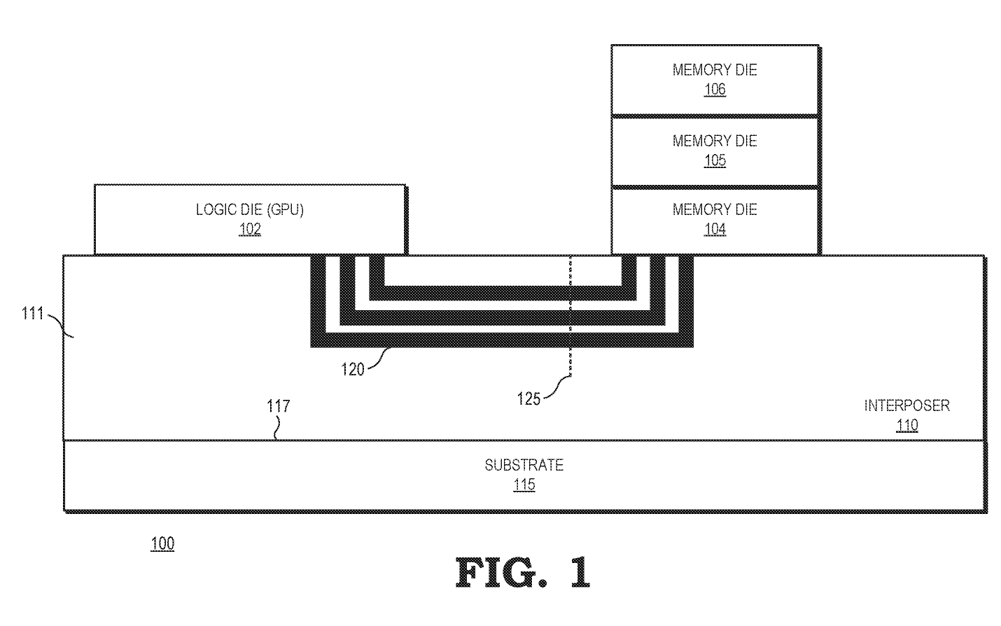

FIGS. 1-5 illustrate techniques for employing an interposer having transmission lines formed of multiple metal layers disposed in a stack orthogonal to a plane formed by a primary surface of a substrate upon which the interposer is mounted. The use of multiple metal layers to form the transmission lines results in each transmission line having a height, or thickness, that is at least equal to the width of the transmission line. In some embodiments, by using multiple metal layers, a transmission line can be formed having a height or thickness that is more than twice or more than three times the width of the transmission line. The transmission line thereby supports improved signal fidelity, including for relatively high speed signals while maintaining a relatively small footprint. Conventional interposer designs, in contrast to the techniques described herein, employ transmission lines formed of a single metal layer. In order to provide for good signal fidelity, the conventional designs increase the width of the single metal layer. The increase in width requires a commensurate increase in the width of the interposer, increasing the overall footprint of an IC that includes the interposer.

FIG. 1 illustrates a block diagram of an integrated circuit (IC) including an interposer incorporating transmission lines that employ multiple metal layers in accordance with some embodiments. In the illustrated example, the IC includes a logic die 102, memory dies 104, 105, and 106, an interposer 110, and a substrate 115. The logic die is an integrated circuit die formed according to any known integrated circuit fabrication technique, and incorporating circuits that collectively compose a logic device, such as a central processing unit (CPU), graphics processing unit (GPU), accelerated processing unit (APU), digital signal processor (DSP) and the like. For purposes of description, it is assumed that the logic die 102 is a GPU. The memory dies 105-106 are integrated circuit dies formed to compose one or more memory modules, such as dynamic random access memory (DRAM) modules.

In the illustrated example, the memory dies 104-106 are formed and mounted in a “stacked die” arrangement, wherein memory die 105 is mounted on top of memory die 104 and memory die 106 is mounted on top of memory die 105. The memory dies 104-106 may be formed and stacked according to any IC die formation and stacking process. For example, in some embodiments the memory dies 104-106 are formed in the same semiconductor wafer and singulated. The singulated dies are then stacked and bonded to form the stacked die arrangement. It will be appreciated that the stacked die arrangement can include more or fewer memory dies than illustrated at FIG. 1.

The memory dies 104-106 are mounted, in their stacked die arrangement, on the interposer 110. In addition, the logic die 102 is mounted laterally to the stacked memory dies 104-106 on the interposer 110. By mounting the logic die 102 laterally to the memory dies 104-106, rather than in a stacked die arrangement, errors such as those resulting from thermal buildup can be reduced. In some embodiments, the logic die 102 and the memory dies 104-106 are each mounted on the interposer 110 via separate sets of microbumps (not shown).

The interposer 110 is mounted on a primary surface 117 of a package substrate 115. In some embodiments, the package substrate forms at least a portion of an integrated circuit package that encapsulates the interposer 110, the logic die 102, and the stack of memory dies 104-106. In some embodiments, the interposer 110 is mounted on the package substrate via a series of solder bumps (not shown) according to conventional mounting techniques.

The interposer 110 includes a substrate 111 and a set of transmission lines 120. The substrate 111 can be formed of glass, silicon, polyimide, FR-4, or other substrate material. The set of transmission lines 120 are formed by multiple metal layers as described further herein, wherein the multiple metal layers are stacked orthogonal to a plane defined by the primary surface 117. In some embodiments, the logic die 102 and the memory dies 104-106 are mounted on the interposer 110 so that the set of transmission lines 120 form an interconnect for transmission of electrical signaling. For example, in some embodiments the logic die 102 and the memory die 104 each include circuitry forming respective physical, or PHY, layers (not shown) for communication of control and data signaling. Thus, for example, the set of transmission lines 120 can be used to communicate clock signals, data for memory access requests (e.g. read and write requests), control information indicating a type of memory access request, memory address information, and the like.

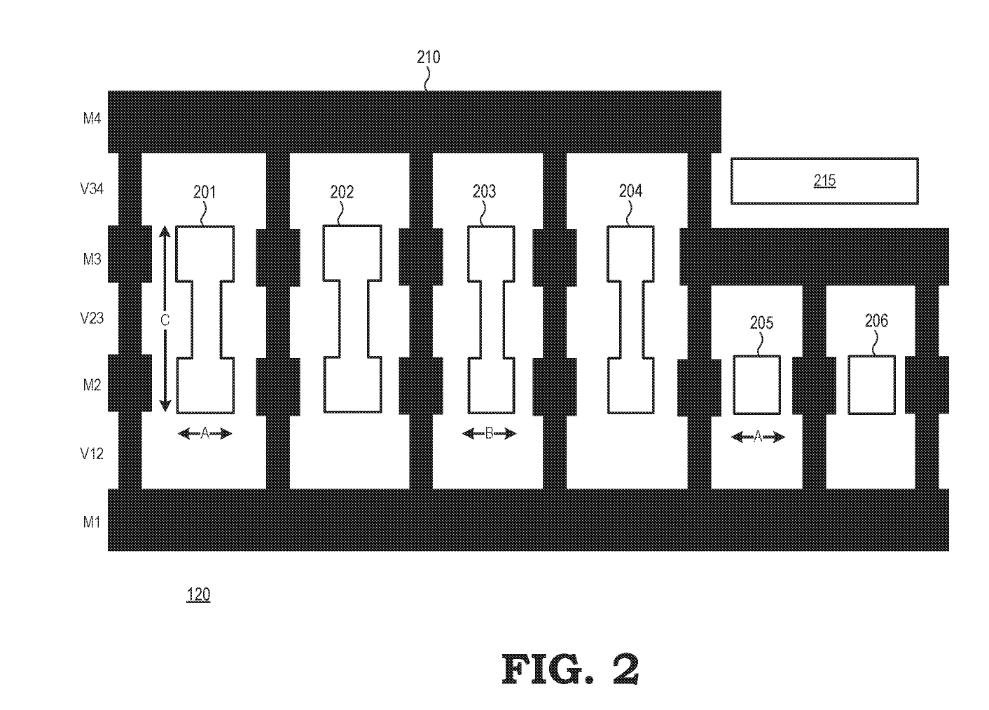

As described further below with respect to the examples of FIGS. 2-4, at least one of the transmission lines 120 is formed with multiple metal layers disposed in a vertical stack, orthogonal to the plane defined by the primary surface 117, so that the height of the transmission line (that is, the thickness of the transmission line between the substrate 115 and the top of the interposer 110 on which the logic die 102 is mounted, as the transmission line runs horizontally) is greater than the width of the transmission line. This provides for improved signal fidelity during transmission along the transmission line while maintaining a relatively small footprint of the interposer 110. In some embodiments one subset (referred to for purposes of description as a “higher-fidelity subset”) of the set of transmission lines 120 are formed with multiple metal layers so that each transmission line in the subset has a height is greater than its width, while a different subset (referred to for purposes of description as a “lower-fidelity subset”) is formed with a single metal layer so that each transmission line in the subset has a height that is equal to or less than its width. The higher-fidelity subset can be used to carry signals that are more sensitive to error, such as clock signals, while the lower-fidelity subset is used to carry signals that are less sensitive to error, such as control signals.

FIGS. 2-4 illustrate different example topologies for the set of transmission lines 120 in accordance with some embodiments. Each of the FIGS. 2-4 is a cross-sectional view of the set of transmission lines 120 at a cut 125 illustrated at FIG. 1. In the example of FIG. 2, the set of transmission lines 120 include transmission lines 201, 202, 203, 204, 205, and 206, as well as a return path 210 and a pad 215. The pad 215 is a metal strip or surface that can be used as a solder or bump pad for mounting a die, such as the logic die 102 or the memory die 104.

Each of the transmission lines 201-204 are formed by stacking three metal layers, designated M2, V23, and M3. The M2 and M3 layers are formed according to any conventional metal layer formation process. In some embodiments, the V23 layer is a via layer, so that the M2 and M3 layers of each transmission line 201-204 is joined by a corresponding via by a conventional via formation process. In at least some embodiments, the via layer for each of the transmission lines 201-204 has a smaller width than the metal layers M2 and M3 of the corresponding transmission line. Each of the transmission lines 201-204 therefore has a “fin” structure whereby it has a greater width at the top and bottom and a smaller width at its center.

Because the transmission lines 204-206 are formed with a vertical stack of three metal layers, each of the transmission lines 204-206 has a greater height than width, thus improving support for signal fidelity without increasing the horizontal footprint of the interposer 110. For example, in some embodiments the width of the transmission line 201 at its widest point (designated width “A” at FIG. 2) is approximately one micron, while the height of each of the metal layers M2, V23, and M3 is one micron each, such that the height or thickness of the transmission line (designated height “C” at FIG. 2) is approximately 3 microns. Transmission line 202 is shaped and dimensioned similarly to transmission line 201.

Transmission line 203 is shaped similarly to transmission line 201, but is thinner, having a width (designated width “B”) of approximately 0.56 microns. However, transmission line 203 is also formed by vertically stacking three metal layers (M2, V23, and M3) and therefore has a height of approximately 3 microns. Transmission line 204 is shaped and dimensioned similarly to transmission line 203. The smaller width of the transmission lines 203 and 204 may support a reduced signal fidelity and smaller overall footprint for the set of transmission lines 120, reducing cost and manufacturing resources. Thus, different transmission lines of the set of transmission lines 120 can be formed of vertical stacked metal layers, with the width adjusted to match a combination of factors including specified signal fidelity support, cost, manufacturing resources, and the like, to support different logic dies and memory dies.

The transmission lines 205 and 206 are formed of a single metal layer, M2. Thus, in some embodiments, the transmission line 205 has a width of approximately one micron and a substantially equal height of one micron. Transmission line 206 is shaped and dimensioned similarly to transmission line 205. Transmission lines 205 and 206 are employed to communicate signals requiring lower fidelity than the signals communicated via the transmission lines 201-204. Thus, using the techniques described herein, transmission lines having multiple vertically stacked metal layers can be combined with transmission lines having a single metal layer in order to support different signal fidelity requirements while conserving manufacturing resources. For example, because the transmission lines 205 and 206 are formed from single metal layers, more space is provided for the pad 215 and ensuring that the set of transmission lines 120 do not increase the footprint of the interposer 110.

In the example of FIG. 2, the return path 210 provides a path for the currents communicated over the transmission lines 201-206 to return. The return path 210 is formed by a stack of metal layers, designated M1, V12, M2, V23, M3, V34, and M4. In addition, the return path 210 is formed so that each of the transmission lines 201-206 is surrounded by metal of the return path 210. Thus, as illustrated, each of the transmission lines 201-206 includes metal of the return path 210, above, below, laterally to one side (e.g. to the left), and laterally to the other side (e.g., to the right) of the corresponding transmission line. This configuration provides for a return path without substantially increasing the footprint of the interposer 110.

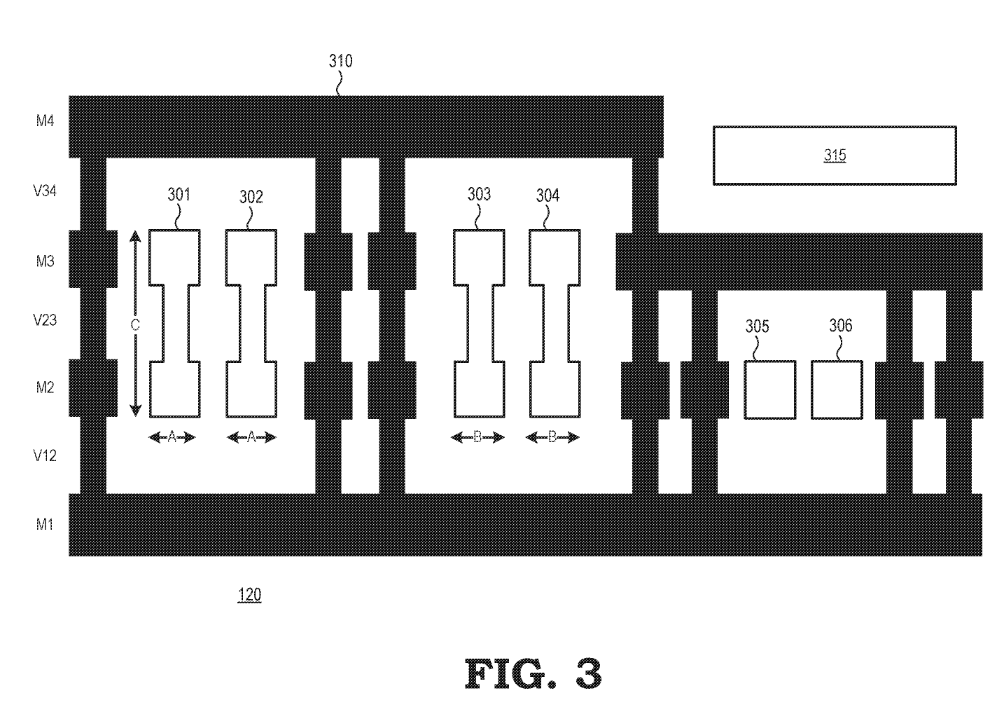

In some embodiments, the return path of the set of transmission lines can be arranged to support differential signaling via the transmission lines. An example is illustrated at FIG. 3 in accordance with some embodiments. The depicted example illustrates transmission lines 301, 302, 303, 304, 305, and 306, as well as a return path 310 and a pad 315. Similar to FIG. 2, the pad 315 is a metal strip or surface that can be used as a solder or bump pad for mounting a die, such as the logic die 102 or the memory die 104.

The transmission lines 301-306 are shaped and dimensioned similarly to transmission lines 201-206, respectively. Thus, each of the transmission lines 301-304 are formed by stacking three metal layers, designated M2, V23, and M3. The M2 and M3 layers are formed according to any conventional metal layer formation process. In some embodiments, the V23 layer is a via layer, so that the M2 and M3 layers of each transmission line 301-304 is joined by a corresponding via by a conventional via formation process. In at least some embodiments, the via layer for each of the transmission lines 301-304 has a smaller width than the metal layers M2 and M3 of the corresponding transmission line. Each of the transmission lines 301-304 therefore has a “fin” structure whereby it has a greater width at the top and bottom and a smaller width at its center. In some embodiments the width of the transmission line 301 at its widest point (designated width “A” at FIG. 3) is approximately one micron, while the height of each of the metal layers M2, V23, and M3 is one micron each, such that the height or thickness of the transmission line approximately 3 microns. Transmission line 302 is shaped and dimensioned similarly to transmission line 302.

Transmission line 303 is shaped similarly to transmission line 301, but is thinner, having a width (designated width “B”) of approximately 0.56 microns. However, transmission line 303 is also formed by vertically stacking three metal layers (M2, V23, and M3) and therefore has a height of approximately 3 microns. Transmission line 304 is shaped and dimensioned similarly to transmission line 303. The transmission lines 305 and 306 are formed of a single metal layer, M2. Thus, in some embodiments, the transmission line 305 has a width of approximately one micron and a height of approximately one micron. Transmission line 306 is shaped and dimensioned similarly to transmission line 305.

Similar to the return path 210, the return path 310 provides a path for the currents communicated over the transmission lines 301-306 to return. The return path 310 is formed by a stack of metal layers, designated M1, V12, M2, V23, M3, V34, and M4. However, in contrast to return path 210, the return path 310 is formed so that each of the transmission lines 301-306 includes metal of the return path laterally to only one side, while laterally to the opposite side is another of the transmission lines 301-306. That is the transmission lines 301-306 are arranged in pairs, with each pair of transmission lines having metal of the return path 310, above, below, laterally to one side (e.g. to the left), and laterally to the other side (e.g., to the right) of the corresponding transmission line pair. In the example of FIG. 3, the transmission lines 301 and 302 form one transmission line pair, transmission lines 303 and 304 form another transmission line pair, and transmission lines 305 and 306 form still another transmission line pair. Each of the transmission line pairs can be employed to together communicate a corresponding differential signal.

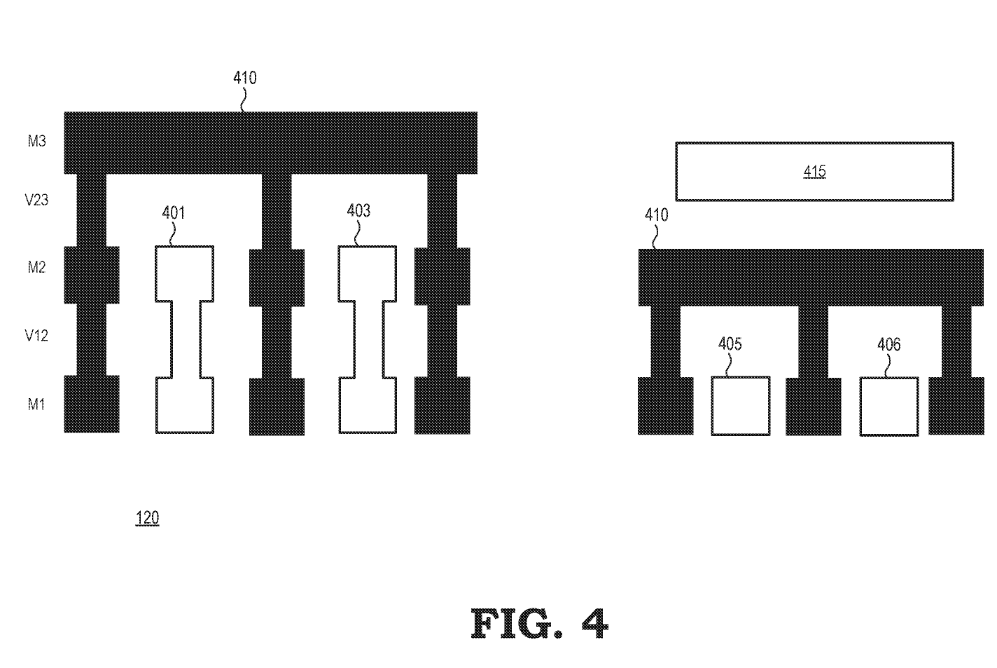

In some embodiments, the return path of the set of transmission lines 120 can be arranged so that it does not surround each transmission line on four sides, but so that one side of the transmission line is not disposed next to the metal of the transmission line. An example is illustrated at FIG. 4 in accordance with some embodiments. The depicted example illustrates transmission lines 401, 403, 405, and 406, as well as a return path 410 and a pad 415. Similar to FIG. 2, the pad 415 is a metal strip or surface that can be used as a solder or bump pad for mounting a die, such as the logic die 102 or the memory die 104.

The transmission lines 401, 403, 405, and 406 are shaped and dimensioned similarly to transmission lines 201, 203, 205, and 206, respectively. Thus, each of the transmission lines 401 and 403 are formed by stacking three metal layers, designated M1, V12, and M2. The M1 and M2 layers are formed according to any conventional metal layer formation process. In some embodiments, the V12 layer is a via layer, so that the M2 and M3 layers of each transmission line 401 and 403 is joined by a corresponding via by a conventional via formation process. In at least some embodiments, the via layer for each of the transmission lines 401 and 403 has a smaller width than the metal layers M1 and M2 of the corresponding transmission line. Each of the transmission lines 401 and 403 therefore has a “fin” structure whereby it has a greater width at the top and bottom and a smaller width at its center. In some embodiments the width of the transmission line 401 at its widest point is approximately one micron, while the height of each of the metal layers M1, V12, and M2 is one micron each, such that the height or thickness of the transmission line approximately 3 microns. Transmission line 303 is shaped similarly to transmission line 301, but is thinner, having a width of approximately 0.56 microns. However, transmission line 403 is also formed by vertically stacking three metal layers (M2, V23, and M3) and therefore has a height of approximately 3 microns. The transmission lines 405 and 406 are formed of a single metal layer, M2. Thus, in some embodiments, the transmission line 405 has a width of approximately one micron and a height of approximately one micron. Transmission line 406 is shaped and dimensioned similarly to transmission line 405.

Similar to the return path 210, the return path 410 provides a path for the currents communicated over the transmission lines 401, 403, 405, and 406 to return. The return path 410 is formed by a stack of metal layers, designated M1, V12, M2, V23, and M3. However, in contrast to return path 210, the return path 410 is formed so that each of the transmission lines 401, 403, 405, and 406 does not include metal of the return path below the corresponding transmission line. That is the transmission lines 401, 403, 405 are arranged with each transmission lines having metal of the return path 310, above, laterally to one side (e.g. to the left), and laterally to the other side (e.g., to the right) of the corresponding transmission line. This reduces the amount of metal employed for the return path, saving manufacturing resources.

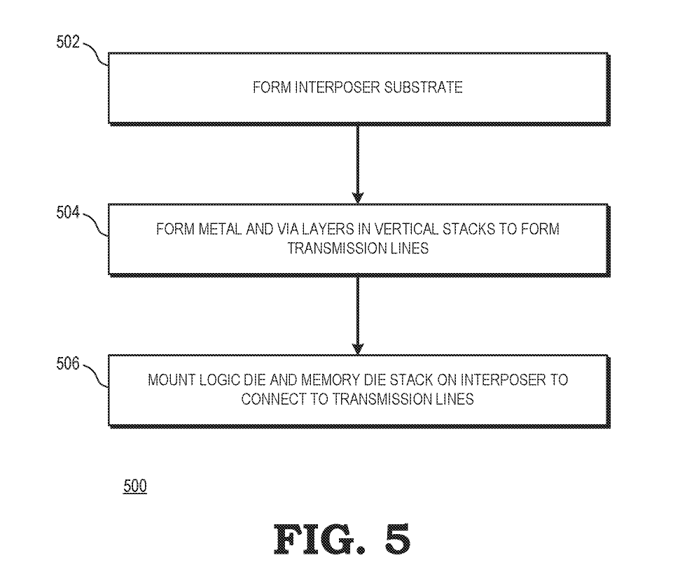

FIG. 5 illustrates a flow diagram of a method 500 of forming an integrated circuit device including an interposer in accordance with some embodiments. At block 502 a substrate for the interposer is formed according to any of a number of semiconductor substrate formation techniques, such as by pulling a seed crystal from a melt to form a boule, and slicing and polishing the boule to form the substrate 111. At block 504, a plurality of metal layers is added to the substrate in vertical stacks to form one or more of the set of transmission lines 120. The metal layers can be formed according to any of a variety of metal layer formation processes. For example, the substrate 111 can be etched to form holes or spaces for the metal layers, the metal layers formed in the holes or spaces to form the vertical stacks, and then substrate material placed over the holes or spaces to embed the metal layers in the substrate 111. At block 506 the stack of memory dies 104-106 and the logic die 102 are each mounted on the interposer 110 via any of a number of die mounting processes. For example, in some embodiments microbumps are mounted on the interposer 110, and the memory die 104 and logic die 102 are each bonded (e.g., soldered) to a respective set of microbumps. The memory die 104 and the logic die 102 are each mounted so that the set of transmission lines 120 form electrical connections between circuits of the respective dies.

In some embodiments, the apparatus and techniques described above are implemented in a system comprising one or more integrated circuit (IC) devices (also referred to as integrated circuit packages or microchips), such as the interposer 110 described above with reference to FIGS. 1-5. Electronic design automation (EDA) and computer aided design (CAD) software tools may be used in the design and fabrication of these IC devices. These design tools typically are represented as one or more software programs. The one or more software programs comprise code executable by a computer system to manipulate the computer system to operate on code representative of circuitry of one or more IC devices so as to perform at least a portion of a process to design or adapt a manufacturing system to fabricate the circuitry. This code can include instructions, data, or a combination of instructions and data. The software instructions representing a design tool or fabrication tool typically are stored in a computer readable storage medium accessible to the computing system. Likewise, the code representative of one or more phases of the design or fabrication of an IC device may be stored in and accessed from the same computer readable storage medium or a different computer readable storage medium.

A computer readable storage medium may include any non-transitory storage medium, or combination of non-transitory storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

1. An apparatus, comprising:
an interposer, including:
a substrate oriented parallel to a plane; and
a plurality of transmission lines, a first transmission line of the plurality of transmission lines comprising a first plurality of metal layers formed in a stack orthogonal to the plane to form the first transmission line as it runs parallel to the plane.

2. The apparatus of claim 1, wherein:
the stack is arranged such that a thickness of the first transmission line is greater than a width of the first transmission line.

3. The apparatus of claim 2, wherein:
the thickness of the first transmission line is at least twice the width of the first transmission line.

4. The apparatus of claim 3, wherein:
the thickness of the first transmission line is at least three times the width of the first transmission line.

5. The apparatus of claim 1, wherein:
a second transmission line of the plurality of transmission lines comprises a second plurality of metal layers formed in a vertical stack, the second transmission line having a different width than the first transmission line.

6. The apparatus of claim 5, wherein:
a third transmission line of the plurality of transmission lines comprises a single metal layer.

7. The apparatus of claim 1, further comprising:
a second transmission line disposed laterally to the first transmission line, wherein the first transmission line and second transmission line together comprise a differential signaling line.

8. The apparatus of claim 1, wherein:
at least one layer of the first plurality of metal layers comprises a via layer.

9. The apparatus of claim 1, wherein the interposer further comprises:
a return path comprising a plurality of metal layers, the return path surrounding the first transmission line on at least three sides.

10. The apparatus of claim 9, wherein the return path surrounds the first transmission line on four sides.

11. The apparatus of claim 1, further comprising:
a plurality of dies in a stacked die arrangement mounted on the interposer.

12. The apparatus of claim 11, further comprising:
a logic die disposed at the interposer and positioned laterally to the plurality of dies.

13. An integrated circuit, comprising:
an interposer, including:
a substrate; and
a plurality of transmission lines, a first transmission line of the plurality of transmission lines comprising a first plurality of metal layers formed in a stack orthogonal to a plane defined by a primary surface of the substrate, the stack forming the first transmission line as it runs parallel to the plane; and
a plurality of dies in a stacked die arrangement disposed at the interposer to connect to the plurality of transmission lines.

14. The integrated circuit of claim 13, wherein:
the stack is arranged such that a thickness of the first transmission line is greater than a width of the first transmission line.

15. The integrated circuit of claim 14, wherein:
the thickness of the first transmission line is at least twice the width of the first transmission line.

16. The integrated circuit of claim 15, wherein:
the thickness of the first transmission line is at least three times the width of the first transmission line.

17. The integrated circuit of claim 14, wherein:
a second transmission line of the plurality of transmission lines comprises a second plurality of metal layers formed in a vertical stack, the second transmission line having a different width than the first transmission line.

18. The integrated circuit of claim 17, further comprising:
a third transmission line of the plurality of transmission lines comprises a single metal layer.

19. The integrated circuit of claim 14, further comprising:
a second transmission line disposed laterally to the first transmission line, the first transmission line and second transmission line to communicate a differential signal.

20. A method of forming an integrated circuit device, comprising:
forming an interposer, comprising:
forming a substrate having a primary surface; and
forming a plurality of metal layers in a stack orthogonal to a plane defined by the primary surface to form a transmission line, the stack forming the transmission line as it runs parallel to the plane; and
mounting a plurality of dies on the interposer to connect to the transmission line.
